(19) United States
(12) Patent Application Publication
(10) Pub. No.: US 2025/0224827 A1
(43) Pub. Date: Jul. 10, 2025

(54) DISPLAY DEVICE AND ELECTRONIC DEVICE INCLUDING THE SAME

(71) Applicant: Samsung Display Co., Ltd., Yongin-Si (KR)

(72) Inventor: Bong Il KANG, Yongin-si (KR)

(21) Appl. No.: 18/945,518

(22) Filed: Nov. 13, 2024

(30) Foreign Application Priority Data
Jan. 10, 2024 (KR) 10-2024-0004186

(51) Int. Cl. G06F 3/041; H10K 59/40

(52) U.S. Cl. CPC G06F 3/0416; G06F 3/0412; H10K 59/40

(57) ABSTRACT

A display device is disclosed that includes an electronic panel, a driver integrated circuit, a touch driver, and a compensation line. The electronic panel includes a touch panel and a display panel, and the touch panel includes a touch electrode and the display panel includes a pixel. The driver integrated circuit provides a data voltage to the pixel and communicates with a processor through a communication line. The touch driver is connected to the touch electrode through a touch line and drives the touch panel. A signal opposite to a signal of the communication line is applied to the compensation line.

### CROSS-REFERENCE TO RELATED APPLICATION

The present application claims priority under 35 U.S.C. § 119 (a) to Korean patent application No. 10-2024-0004186 filed on Jan. 10, 2024, in the Korean Intellectual Property Office, the entire disclosure of which is incorporated herein by reference.

### BACKGROUND

### 1. Technical Field

The present disclosure generally relates to a display device, and more particularly, to a display device including a touch panel.

### 2. Related Art

With the development of information technologies, the importance of display devices which are connection mediums between users and information has increased. Accordingly, display devices such as liquid crystal display devices and organic light emitting display devices are increasingly used.

### SUMMARY

Embodiments may provide a display device for compensating for influence which a communication line has on a touch line.

An embodiment of a display device includes: an electronic panel including a touch panel and a display panel, the touch panel includes a touch electrode and the display panel includes a pixel; a driver integrated circuit that provides a data voltage to the pixel, the driver integrated circuit communicates with a processor through a communication line; a touch driver connected to the touch electrode through a touch line, the touch driver drives the touch panel; and a compensation line to which a signal opposite to a signal of the communication line is applied.

The compensation line may overlap with at least a portion of the touch line on a plane.

The communication line may overlap with at least a portion of the touch line on a plane.

The compensation line may be adjacent to at least a portion of the touch line.

At least a portion of the compensation line may be disposed on the touch line.

At least a portion of the compensation line may be disposed between the touch line and the communication line.

The touch driver may apply the signal opposite to the signal of the communication line to the compensation line.

The touch driver may be disposed on a flexible printed circuit connected to the electronic panel. The compensation line may extend to the electronic panel in the flexible printed circuit.

The compensation line may be adjacent to the touch line in the electronic panel.

The driver integrated circuit may apply a signal opposite to the signal of the communication line to the compensation line.

The driver integrated circuit may be disposed in the electronic panel. The compensation line may be adjacent to the touch line in the electronic panel.

An embodiment of a display device includes: an electronic panel including a touch panel and a display panel, the touch panel includes a touch electrode and the display panel includes a pixel; a driver integrated circuit that provides a data voltage to the pixel, the driver integrated circuit communicates with a processor through a communication line; and a touch driver connected to the touch electrode through a touch line, the touch driver drives the touch panel, the touch driver senses a signal of the communication line through a sensing line, the touch driver compensates for a signal of the touch line, based on the signal of the communication line.

The sensing line may overlap with at least a portion of the communication line on a plane. The sensing line may form a capacitor with the communication line on a plane.

The communication line may overlap with at least a portion of the touch line on a plane.

The sensing line may be adjacent to at least a portion of the communication line.

At least a portion of the sensing line may be disposed between the communication line and the touch line.

The touch driver may be disposed in a flexible printed circuit connected to the electronic panel. The sensing line may extend to the electronic panel in the flexible printed circuit. The sensing line may be adjacent to the communication line in the electronic panel.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a view illustrating a display device in accordance with embodiments of the present disclosure.

FIG. 2 is a view illustrating a display device in accordance with embodiments of the present disclosure.

FIG. 3 is a sectional view of the display device shown in FIG. 1.

FIG. 4 is a sectional view illustrating an electronic panel shown in FIG. 3.

FIG. 5 is a sectional view illustrating a display panel shown in FIG. 4.

FIG. 6 is a plan view illustrating a portion of the electronic panel shown in FIG. 4.

FIG. 7 is a plan view illustrating a portion of the electronic panel shown in FIG. 4.

FIG. 8 is a plan view illustrating the display device shown in FIG. 1.

FIG. 9 is a sectional view taken along line I-I′ shown in FIG. 8.

FIG. 10 is a comparative example illustrating influence which a communication line has on a touch line.

FIG. 11 is a view illustrating compensation through a compensation line shown in FIG. 8.

FIG. 12 is a sectional view illustrating another example taken along the line I-I′ shown in FIG. 8.

FIG. 13 is a plan view illustrating a display device in accordance with embodiments of the present disclosure.

FIG. 14 is a sectional view taken along line II-II′ shown in FIG. 13.

FIG. 15 is a plan view illustrating a display device in accordance with embodiments of the present disclosure.

FIG. 16 is a block diagram illustrating an electronic device in accordance with embodiments of the present disclosure.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

When an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Hereinafter, exemplary embodiments of the present disclosure will be described in more detail with reference to the accompanied drawings.

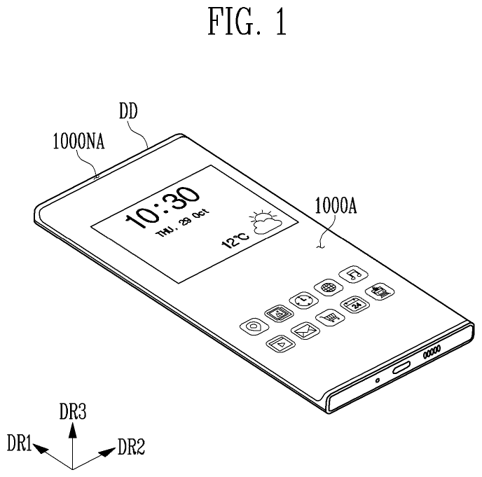

FIG. 1 is a view illustrating a display device in accordance with embodiments of the present disclosure.

Referring to FIG. 1, the display device DD may be a device which is activated according to an electrical signal. For example, the display device DD may be a mobile phone, a tablet computer, a vehicle navigation system, a game console, or a wearable device, but the present disclosure is not limited thereto. In FIG. 1, it is exemplarily illustrated that the display device DD is a mobile phone.

An active area 1000A and a peripheral area 1000NA may be defined in the display device DD. The display device DD may display an image through the active area 1000A. The active area 1000A may include a surface defined by a first direction DR1 and a second direction DR2. The peripheral area 1000NA may surround the periphery of the active area 1000A.

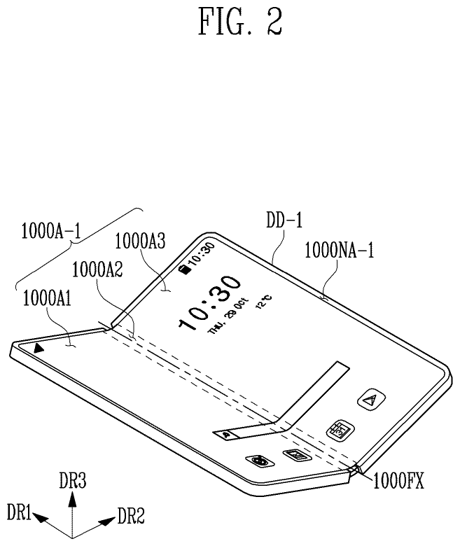

FIG. 2 is a view illustrating a display device in accordance with embodiments of the present disclosure. In FIG. 2, components described with reference to FIG. 1 are designated by like reference numerals, and their descriptions will be omitted.

In FIG. 2, a state in which the display device DD-1 is folded at a predetermined angle is illustrated. Referring to FIG. 2, in a state in which the display device DD-1 is unfolded, an active area 1000A-1 may include a plane defined by the first direction DR1 and the second direction DR2.

The active area 1000A-1 may include a first area 1000A1, a second area 1000A2, and a third area 1000A3. The first area 1000A1, the second area 1000A2, and the third area 1000A3 may be sequentially defined. The second area 1000A2 may be bent with respect to a folding axis 1000FX extending along the first direction DR1. Therefore, the first area 1000A1 and the third area 1000A3 may be designated as unfolding areas, and the second area 1000A2 may be designated as a folding area.

When the display device DD-1 is folded, the first area 1000A1 and the third area 1000A3 may face each other. Therefore, in the display device DD-1 is completely folded, the active area 1000A-1 may not be exposed to the outside, and this may be designated as in-folding. However, this is merely illustrative, and an operation of the display device DD-1 is not limited thereto.

When the display device DD-1 is folded, the first area 1000A1 and the third area 1000A3 may be opposite to each other. Therefore, in a state in which the display device DD-1 is folded, the active area 1000A-1 may be exposed to the outside, and this may be designated as out-folding.

In an embodiment, the display device DD-1 may perform only any one of an in-folding operation and an out-folding operation. In an embodiment, the display device DD-1 may perform both the in-folding operation and the out-folding operation. The same area, e.g., the second area 1000A1 of the display device DD-1 may be in-folded and out-folded.

In FIG. 2, one folding area and two unfolding areas are illustrated as an example. However, the number of folding and unfolding areas is not limited thereto. For example, the display device DD-1 may include a plurality of unfolding areas of which number is greater than 2 and a plurality of folding areas disposed between adjacent unfolding areas.

In FIG. 2, it is exemplarily illustrated that the folding axis 1000FX extends in the first direction DR1. However, the present disclosure is not limited thereto. For example, the folding axis 1000FX may extend along a direction parallel to the second direction DR2. The first area 1000A1, the second area 1000A2, and the third area 1000A3 may be sequentially arranged along the first direction DR1.

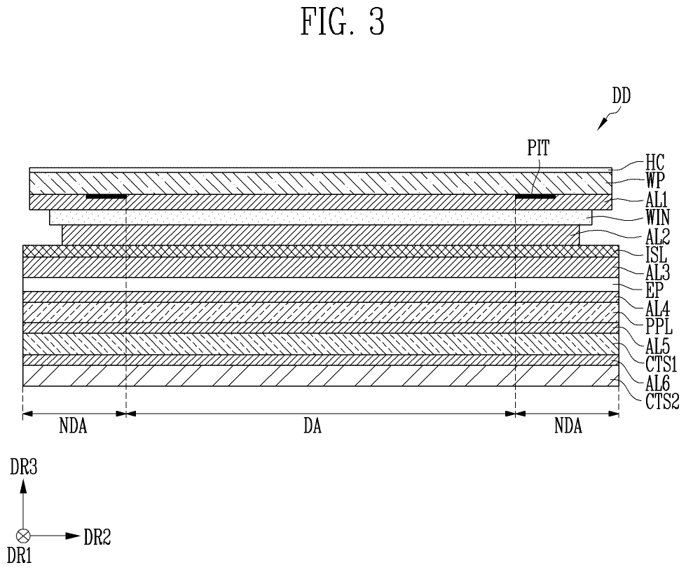

FIG. 3 is a sectional view of the display device shown in FIG. 1.

Referring to FIG. 3, the display device DD may include an electronic panel EP, an impact absorbing layer ISL, a panel protective layer PPL, a first conductive sheet CTS1, a second conductive sheet CTS2, a window WIN, a window protective layer WP, a hard coating layer HC, and first to sixth adhesive layers AL1 to AL6.

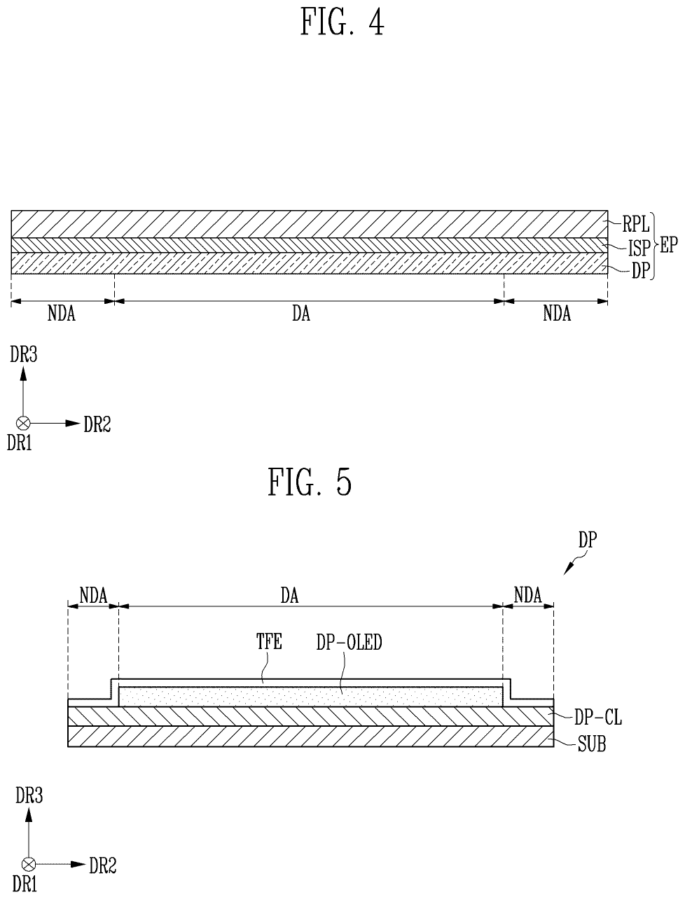

The electronic panel EP may display an image, sense touches, and decrease the reflectivity of external light. The electronic panel EP may include a display panel, a touch panel, and a reflection preventing layer, and a configuration of the electronic panel EP will be described below in FIG. 4.

The impact absorbing layer ISL may be disposed on the electronic panel EP. The impact absorbing layer ISL may absorb external impact applied toward the electronic panel EP from the top of the display device DD, thereby protecting the electronic panel EP. The impact absorbing layer ISL may be manufactured in the form of a stretched film.

The impact absorbing layer ISL may include a flexible plastic material. The flexible plastic material may be defined as a synthetic resin film. For example, the impact absorbing layer ISL may include a flexible plastic material such as polyimide (PI) or polyethylene terephthalate (PET).

The panel protective layer PPL may be disposed below the electronic panel EP. The panel protective layer PPL may protect the bottom of the electronic panel EP. The panel protective layer PPL may include a flexible plastic material. For example, the panel protective layer PPL may include polyethylene terephthalate (PET).

The first conductive sheet CTS1 may be disposed below the panel protective layer PPL. The second conductive sheet CTS2 may be disposed below the first conductive sheet CTS1. The first conductive sheet CTS1 and the second conductive sheet CTS may include a metal.

The first conductive sheet CST1 may include a ferromagnetic material. For example, the first conductive sheet CTS1 may be defined as a ferrite sheet including ferrite. The second conductive sheet CTS2 may include a diamagnetic material. For example, the second conductive sheet CTS2 may be defined as a copper sheet including copper. The first and second conductive sheets CTS1 and CTS2 may shield an external magnetic field such that the external magnetic field is not applied to the electronic panel EP from the bottom of the display device DD.

The window WIN may be disposed on the impact absorbing layer ISL. The window WIN may protect the electronic panel EP from external scratches. The window WIN may have an optically transparent property. The window WIN may include glass. However, the present disclosure is not limited thereto, and the window WIN may include a synthetic resin film.

The window WIN may have a multi-layer structure or a single-layer structure. For example, the window WIN may include a plurality of synthetic resin films bonded to each other with an adhesive, or include a glass substrate and a synthetic resin film, which are bonded to each other with an adhesive.

The window protective layer WP may be disposed on the window WIN. The window protective layer WP may include a flexible plastic material such as polyimide or polyethylene terephthalate. The hard coating layer HC may be disposed on a top surface of the window protective layer WP.

A printing layer PIT may be disposed on a bottom surface of the window protective layer WP. The printing layer PIT may have a black color, but the color of the printing layer PIT is not limited thereto. The printing layer PIT may be adjacent to an edge of the window protective layer WP. The printing layer PIT may overlap with a non-display area NDA.

The first adhesive layer AL1 may be disposed between the window protective layer WP and the window WP WIN. The window protective layer WP and the window WIN may be joined with each other by the first adhesive layer AL1. The first adhesive layer AL1 may cover the printing layer PIT.

The second adhesive layer AL2 may be disposed between the window WIN and the impact absorbing layer ISL. The window WIN and the impact absorbing layer ISL may be joined with each other by the second adhesive layer AL2.

The third adhesive layer AL3 may be disposed between the impact absorbing layer ISL and the electronic panel EP. The impact absorbing layer ISL and the electronic panel EP may be joined with each other by the third adhesive layer AL3.

The fourth adhesive layer AL4 may be disposed between the electronic panel EP and the panel protective layer PPL. The electronic panel EP and the panel protective layer PPL may be joined with each other by the fourth adhesive layer AL4.

The fifth adhesive layer AL5 may be disposed between the panel protective layer PPL and the first conductive sheet CTS1. The panel protective layer PPL and the first conductive sheet CTS1 may be joined with each other by the fifth adhesive layer AL5.

The sixth adhesive layer AL6 may be disposed between the first conductive sheet CTS1 and the second conductive sheet CTS2. The first conductive sheet CTS1 and the second conductive sheet CTS2 may be joined with each other by the sixth adhesive layer AL6.

The first to sixth adhesive layers AL1 to AL6 may include a Pressure Sensitive Adhesive (PSA) or an Optically Clear Adhesive (OCA), but the kind of adhesive is not limited thereto. FIG. 4 is a sectional view illustrating the electronic panel shown in FIG. 3.

Referring to FIG. 4, the electronic panel EP may include a display panel DP, a touch panel ISP disposed on the display panel DP, and a reflection preventing layer RPL disposed on the touch panel ISP. The display panel DP may be a flexible display panel. For example, the display panel DP may include a flexible substrate and a plurality of elements disposed on the flexible substrate.

In an embodiment, the display panel DP may be a light emitting display panel. However, the present disclosure is not limited to the kind of the display panel DP. For example, the display panel DP may be an organic light emitting display panel, a quantum dot display panel, a micro LED display panel, or a nano LED display panel. A light emitting layer of the organic light emitting display panel may include an organic light emitting material. A light emitting layer of the quantum dot display panel may include a quantum dot, a quantum rod, and the like. A light emitting layer of the micro LED display panel may include a micro LED. A light emitting layer of the nano LED display panel may include a nano LED. Hereinafter, the display panel DP is described as the organic light emitting display panel.

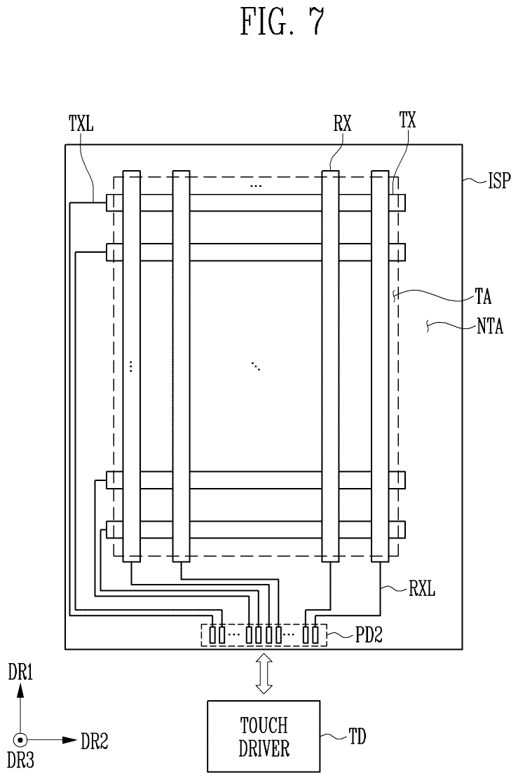

The touch panel ISP may include touch electrodes (hereinafter, shown in FIG. 7) for sensing a touch. The touch panel ISP may be formed directly on the display panel DP when the electronic panel EP is manufactured.

The reflection preventing layer RPL may be disposed on the touch panel ISP. The reflection preventing layer RPL may be formed directly on the touch panel ISP when the electronic panel EP is manufactured. The reflection preventing layer RPL may be defined as an external light reflection preventing film. The reflection preventing layer RPL may decrease the reflectivity of external light incident toward the display panel DP from the top of the display device DD.

Exemplarily, the touch panel ISP may be formed directly on the display panel DP, and the reflection preventing layer RPL may be formed directly on the touch panel ISP. However, the present disclosure is not limited thereto. For example, the touch panel ISP may be separately manufactured to be attached to the display panel DP by an adhesive layer, and the reflection preventing layer RPL may be separately manufactured to be attached to the touch panel ISP by an adhesive layer.

FIG. 5 is a sectional view illustrating the display panel shown in FIG. 4.

Referring to FIG. 5, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA at the periphery of the display area DA. The substrate SUB may include a flexible plastic material such as polyimide (PI).

The substrate SUB may be a member which provides a base surface on which the circuit element layer DP-CL is disposed. The substrate SUB may be a glass substrate, a metal substrate, or a polymer substrate. However, the embodiment is not limited thereto, and the substrate SUB may be an inorganic layer, an organic layer, or a composite material layer.

The substrate SUB may have a multi-layer structure. For example, the substrate SUB may include a first synthetic resin layer, a silicon oxide (SiOx) layer disposed on the first synthetic resin layer, an amorphous silicon (a-Si) layer disposed on the silicon oxide layer, and a second synthetic resin layer disposed on the amorphous silicon layer. The silicon oxide layer and the amorphous silicon layer may be designated as a base barrier layer.

Each of the first and second synthetic resin layers may be one including a polyimide-based resin. Also, each of the first and second synthetic resin layers may be one including at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, the “R”-based resin means one including a functional group of “R.”

The circuit element layer DP-CL may be disposed on the substrate SUB. The circuit element layer DP-CL may include an insulating layer, a semiconductor pattern, a conductive pattern, a signal line, and the like. An insulating layer, a semiconductor layer, and a conductive layer may be formed on the substrate SUB through a process such as coating or deposition. Then, the insulating layer, the semiconductor layer, and the conductive layer may be selectively patterned through a photolithography process which is performed plural times. After that, the semiconductor pattern, the conductive pattern, and the signal line, which are included in the circuit element layer DP-CL, may be formed.

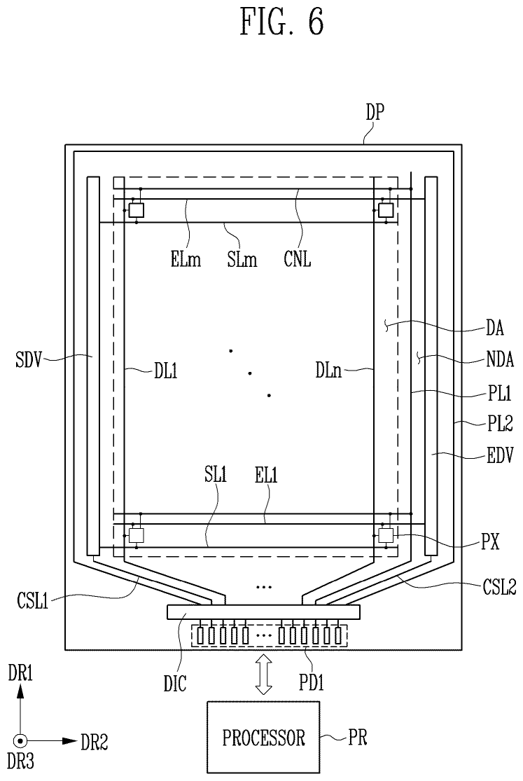

The display element layer DP-OLED may be disposed on the circuit element layer DP-CL. The display element layer DP-OLED may be disposed in the display area DA. A plurality of pixels (hereinafter, shown in FIG. 6) may be disposed in the display area DA. Each of the pixels (hereinafter, shown in FIG. 6) may include a light emitting element connected to a transistor disposed in the circuit element layer DP-CL to be disposed in the display element layer DP-OLED.

The thin film encapsulation layer TFE may be disposed on the circuit element layer DP-CL to cover the display element layer DP-OLED. The thin film encapsulation layer TFE may include inorganic layers and an organic layer between the inorganic layers. The inorganic layers may protect the pixels from moisture/oxygen. The organic layer may protect the pixels from foreign matters such as dust particles.

FIG. 6 is a plan view illustrating a portion of the electronic panel shown in FIG. 4.

Referring to FIG. 6, the electronic panel EP (see FIG. 4) may include a display panel DP, a scan driver SDV, a data driver, an emission driver EDV, and a plurality of first pads PD1. The data driver may be included in a driver integrated circuit DIC.

The display panel DP may have a rectangular shape having long sides extending in the first direction DR1 and short sides extending in the second direction DR2. However, the shape of the display panel DP is not limited thereto. The display panel DP may include a display area DA and a non-display area NDA surrounding the display area DA.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power lines PL1 and PL2, and connection lines CNL. Here, m and n are positive integers.

The pixels PX may be disposed in the display area DA. Each of the scan driver SDV and the emission driver EDV may be disposed in the non-display area NDA adjacent to each of the long sides of the display panel DP. The driver integrated circuit DIC may be disposed in the non-display area NDA adjacent to one of the short sides of the display panel DP. When viewed on a plane, the driver integrated circuit DIC may be adjacent to a lower end of the display panel DP.

The scan lines SL1 to SLm may extend in the second direction DR2 to be connected to the pixels PX and the scan driver SDV. The data lines DL1 to DLn may extend in the first direction DR1 to be connected to the pixels PX and the driver integrated circuit DIC. The emission lines EL1 to ELm may extend in the second direction DR2 to be connected to the pixels PX and the emission driver EDV.

The first power line PL1 may be disposed in the non-display area NDA while extending in the first direction DR1. The first power line PL1 may be disposed between the display area DA and the emission driver EDV. The first power line PL1 may be connected to the driver integrated circuit DIC.

The connection lines CNL may extend in the second direction DR2 and be arranged in the first direction DR1 to be connected to the first power line PL1 and the pixels PX. A first voltage may be applied to the pixels through the first power line PL1 and the connection lines CNL, which are connected to each other.

The second power line PL2 may be disposed in the non-display area NDA, and extend along the long sides of the display panel DP and another short side of the display panel DP, at which the driver integrated circuit DIC is not disposed. The second power line PL2 may be disposed outwardly of the scan driver SDV and the emission driver EDV. The second power line PL2 may be connected to the driver integrated circuit DIC.

Although not shown in the drawing, the second power line PL2 may extend toward the display area DA to be connected to the pixels PX. A second voltage having a level lower than a level of the first voltage may be applied to the pixels PX through the second power line PL2.

The first control line CSL1 may be connected to the scan driver SDV, and extend toward the driver integrated circuit DIC. The second control line CSL2 may be connected to the emission driver EDV, and extend toward the driver integrated circuit DIC. The driver integrated circuit DIC may be connected to the first control line CSL1 and the second control line CSL2.

The first pads PD1 may be disposed in the non-display area NDA adjacent to the lower end of the display panel DP, and be more adjacent to the lower end of the display panel DP than the driver integrated circuit DIC. The driver integrated circuit DIC may be connected to the first pads PD1. The data lines DL1 to DLn may be connected to the driver integrated circuit DIC, and the driver integrated circuit DIC may be connected to first pads PD1 corresponding to the data lines DL1 to DLn.

The driver integrated circuit DIC may include a timing controller for controlling operations of the scan driver SDV, the data driver, and the emission driver EDV and a voltage generator for generating the first and second voltages. The timing controller and the voltage generator may be connected to the pads PD1. That is, the timing controller or the voltage generator may be integrated with the data driver and the driver integrated circuit DIC. However, in the present disclosure, all of the timing controller, the voltage generator, and the data driver are not necessarily integrated into one, and at least some of the timing controller, the voltage generator, and the data driver may be included in the data integrated circuit DIC.

The scan driver SDV may generate a plurality of scan signals, and the scan signals may be applied to the pixels PX through the scan lines SL1 to SLm. The data driver may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages provided in response to the scan signals. The pixels PX may emit lights with luminances corresponding to the data voltages in response to the emission signals, thereby displaying an image.

The driver integrated circuit DIC may communicate with a processor PR. The processor PR may include at least one of a central processing unit (CPU) and an application processor (AP). The processor PR may further include at least one of a graphic processing unit (GPU), a communication processor (CP), and an image signal processor (ISP). The processor PR may further include a neural processing unit (NPU). At least two of the above-described processing units may be implemented into one integrated component (e.g., a single chip), or be respectively implemented as independent components (e.g., a plurality of chips).

The timing controller may receive input image data from the processor PR, and output a data signal to the data driver by converting a data format of the input image data to be suitable for interface specifications of the display panel DP. The timing controller may output various control signals necessary for driving of the display panel DP.

FIG. 7 is a plan view illustrating a portion of the electronic panel shown in FIG. 4.

Referring to FIG. 7, the electronic panel EP (see FIG. 4) may include a touch panel ISP. The touch panel ISP may be driven by a touch driver TD.

The touch panel ISP may include touch electrodes TX and RX, touch lines TXL and RXL electrically connected to the touch electrodes TX and RX, and second pads PD2 electrically connecting the touch lines TXL and RXL to the touch driver TD.

A touch area TA and a non-touch area NTA adjacent to the touch area TA may be defined in the touch panel ISP. When viewed on a plane, the touch area TA may overlap with the display area DA (see FIG. 6), and the non-touch area NTA may overlap with the non-display area NDA (see FIG. 6).

The touch electrodes TX and RX may be disposed in the touch area TA, and the second pads PD2 may be disposed in the non-touch area NTA. The second pads PD2 may be adjacent to a lower end of the touch panel ISP. However, the present disclosure is not limited to positions of the second pads PD2.

First touch electrodes TX may extend in the second direction DR2 to be arranged in the first direction DR1. Each of the first touch electrodes TX may be connected to a second pad PD2 through a first touch line TXL. The second pad PD2 may electrically connect the first touch electrode TX to the touch driver TD.

Second touch electrodes RX may extend in the first direction DR1 to be arranged in the second direction DR2. Each of the second touch electrodes RX may be connected to a second pad PD2 through a second touch line RXL. The second pad PD2 may electrically connect the second touch electrode RX to the touch driver TD.

In an embodiment, the touch panel ISP may be driven in a mutual capacitance manner. In the mutual capacitance manner, any one of the first touch electrode TX and the second touch electrode RX may serve as a touch driving electrode, and the other of the first touch electrode TX and the second touch electrode RX may serve as a touch sensing electrode. A touch driving signal may be input to the touch driving electrode, and a touch sensing signal is output from the touch sensing electrode. In some embodiments, the first touch electrode TX may receive a touch driving signal for touch driving, and the second touch electrode RX may output a touch sensing signal corresponding to the touch driving signal. Alternatively, in some embodiments, the second touch electrode RX may receive a touch driving signal, and the second touch electrode RX may output a touch sensing signal corresponding to the touch driving signal. Hereinafter, for convenience of description, a case where the touch driving signal is input to the first touch electrode TX and the second touch electrode RX outputs a touch sensing signal is described as an example. However, embodiments of the present disclosure are not limited thereto.

A capacitance may be formed between the first touch electrode TX and the second touch electrode RX. For example, the first touch electrode TX and the second touch electrode RX may be disposed while overlapping with each other in a vertical direction (e.g., a third direction DR3) in an area in which the first touch electrode TX and the second touch electrode RX overlap with each other. In the area in which the first touch electrode TX and the second touch electrode RX overlap with each other, the first touch electrode TX may serve as one electrode of the capacitor, and the second touch electrode RX may serve as the other electrode of the capacitor. In the area in which the first touch electrode TX and the second touch electrode RX overlap with each other, a capacitance may be formed between the first touch electrode TX and the second touch electrode RX. When an object (e.g., a finger of a user, a stylus pen, or the like) approaches toward the touch panel ISP, a capacitance value may vary. The touch driver TD may detect whether a touch has been input or a position of the touch, based on the varied capacitance value.

However, the present disclosure is not limited to the manner in which the touch panel ISP is driven. For example, the touch panel ISP may be driven in a self-capacitance manner.

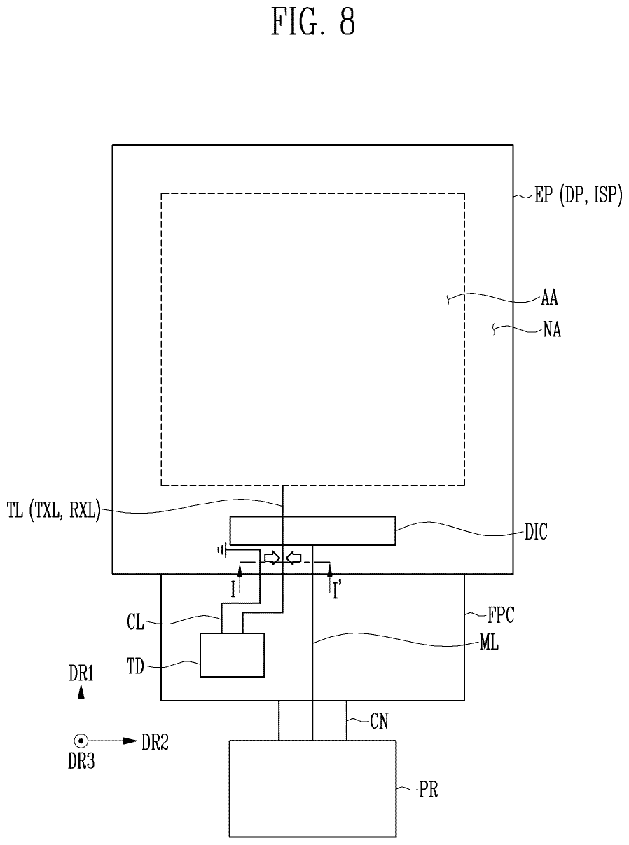

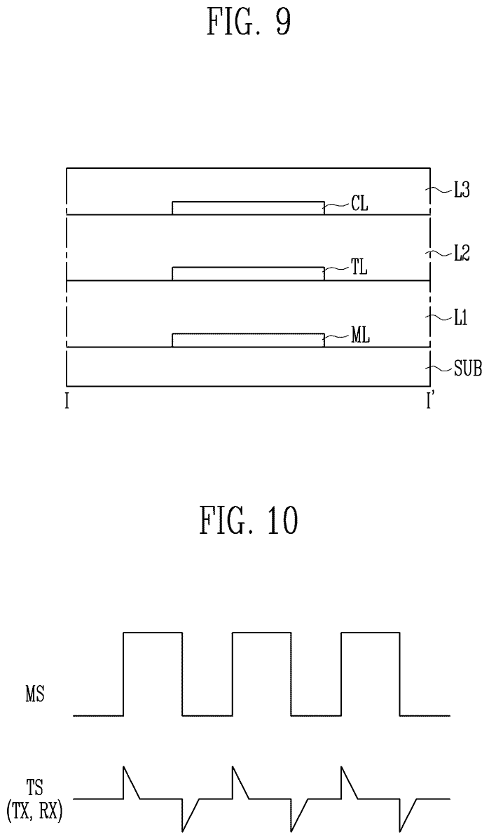

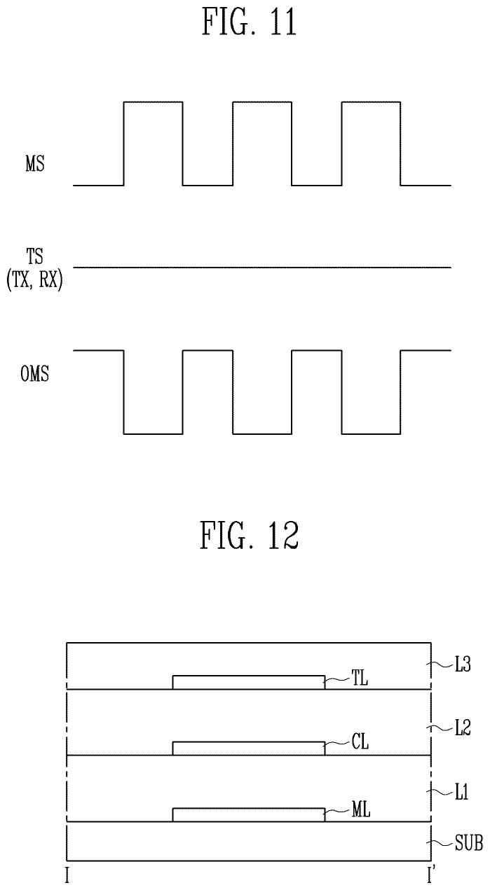

FIG. 8 is a plan view illustrating the display device shown in FIG. 1, and FIG. 9 is a sectional view taken along line I-I′ shown in FIG. 8. FIG. 10 is a comparative example illustrating influence which a communication line has on a touch line. FIG. 11 is a view illustrating compensation through a compensation line shown in FIG. 8.

In FIG. 8, for convenience of description, pads between an electronic panel EP, a flexible printed circuit FPC, a connection portion CN, and a processor PR will be omitted.

In FIG. 8, for convenience of description, although a specific line is disposed in a plurality of components (e.g., the electronic panel EP, the flexible printed circuit FPC, the connection portion CN, and the processor PR) through pads, the specific line will be regarded as one line.

For convenience of description, FIG. 8 illustrates that a touch line TL traverses a driver integrated circuit DIC. However, the present disclosure is not limited thereto. For example, the touch line TL may be connected to a touch driver TD bypassing the driver integrated circuit DIC.

For convenience of description, FIG. 8 illustrates that a compensation line CL, the touch line TL, and a communication line ML are spaced apart from each other. However, the compensation line CL, the touch line TL, and the communication line ML are not necessarily spaced apart from each other, and at least two of the compensation line CL, the touch line TL, and the communication line ML may partially overlap with each other on a plane.

FIG. 9 is for the purpose of illustrating relative positions between the lines ML, CL, and TL. For convenience of description, only a substrate SUB, a first layer L1, a second layer L2, and a third layer L3 are illustrated, and components between the first layer L1, the second layer L2, and the third layer L3 and on the third layer L3 will be omitted.

FIG. 10 is a view illustrating a case where the compensation line CL does not exist.

Referring to FIG. 8, the electronic panel EP may include an active area AA and a peripheral area NA adjacent to the active area AA. The active area AA may be an area overlapping with the display area DA (see FIG. 6) and the touch area TA (see FIG. 7). The peripheral area NA may be an area except the active area AA in the electronic panel EP.

The driver integrated circuit DIC may communicate with the processor PR through the communication line ML. For example, the communication line ML may be connected to the processor PR while traversing the flexible printed circuit FPC and the connection portion CN from the peripheral area NA.

The driver integrated circuit DIC and the processor PR may communicate with each other, using a Mobile Industry Processor Interface (MIPI) scheme. For example, the communication line ML may transmit signals according to a MIPI standard. However, the present disclosure is not limited to this interface.

A touch panel ISP may be connected to the touch driver TD through the touch line TL. For example, the touch line TL may connect the touch electrodes TX and RX (see FIG. 7) to the touch driver TD.

The touch driver TD may be disposed in the flexible printed circuit FPC connected to the electronic panel EP. The touch line TL may extend to the electronic panel EP in the flexible printed circuit FPC.

The display device may further include the compensation line CL for compensating for influence which the communication line ML has on the touch line TL. This will be described in detail with reference to FIG. 11.

Referring to FIGS. 8 to 10, the communication line ML may be adjacent to at least a portion of the touch line TL. For example, the communication line ML may be adjacent to at least a portion of the touch line TL in the peripheral area NA.

In an embodiment, the communication line ML may overlap with at least a portion of the touch line TL on a plane. For example, the communication line ML may overlap with at least a portion of the touch line TL in the peripheral area NA.

In this embodiment, it is illustrated that the communication line ML is adjacent to or overlaps with the touch line TL in the peripheral area NA. However, the present disclosure is not limited thereto. For example, the communication line ML and the touch line TL may be adjacent to or overlap with each other in the flexible printed circuit FPC.

As the communication line ML is adjacent to or overlaps with the touch line TL, a capacitor may be formed between the communication line ML and the touch line TL. Accordingly, as shown in FIG. 10, noise may generated in a signal TS of the touch line TL as a signal MS of the communication line ML rises and falls.

In FIG. 9, it is illustrated that the communication line ML and the touch line TL completely overlap with each other. However, the present disclosure is not limited thereto. For example, as the communication line ML and the touch line TL are adjacent to each other, noise may be generated even though the communication line ML and the touch line TL partially overlap with each other or do not overlap with each other.

Referring to FIGS. 8, 9, and 11, the touch driver TD may apply a signal opposite to the signal MS of the communication line ML to the communication line CL. For example, a signal OMS of the compensation line CL may fall when the signal MS of the communication line ML rises, and rise when the signal MS of the communication line ML falls.

It is not necessary that a magnitude of the opposite signal be equal to the opposite of a magnitude of the signal MS of the communication line ML.

The compensation line CL may be adjacent to at least a portion of the touch line TL. For example, the compensation line CL may extend to the electronic panel EP in the flexible printed circuit FPC.

In an embodiment, the compensation line CL may overlap with at least a portion of the touch line TL on a plane. For example, the compensation line CL may overlap with at least a portion of the touch line TL in the peripheral area NA.

As shown in the cross-sectional view of FIG. 9, at least a portion of the compensation line CL may be disposed on the touch line TL, and the touch line TL may be disposed between the communication line ML and the compensation line CL. For example, the second layer L2 including the touch line TL may be disposed on the first layer L1 including the communication line ML, and the third layer L3 including the compensation line CL may be disposed on the second layer L2.

As the compensation line CL is adjacent to or overlaps with the touch line TL, a capacitor may be formed between the compensation line CL and the touch line TL. Accordingly, as shown in FIG. 11, noise caused by the communication line ML may be compensated as the signal OMS is opposite to the signal MS of the communication line ML.

In FIG. 9, it is illustrated that the compensation line CL and the touch line TL completely overlap with each other. However, the present disclosure is not limited thereto. For example, as the compensation line CL and the touch line TL may be adjacent to each other, and the signal TS of the touch line TL may be compensated even though the compensation line CL and the touch line TL partially overlap with each other or do not overlap with each other.

FIG. 12 is a sectional view illustrating another example taken along the line I-I′ shown in FIG. 8.

A display device shown in FIG. 12 is substantially identical to the display device shown in FIG. 9, except relative positions of the lines ML, CL, and TL. Therefore, components identical or similar to those shown in FIG. 9 are designated by like reference numerals, and overlapping descriptions will be omitted.

Referring to FIG. 12, at least a portion of the compensation line CL may be disposed between the touch line TL and the communication line ML on a section. For example, a second layer L2 including the compensation line CL may be disposed on a first layer L1 including the communication line ML, and a third layer L3 including the touch line TL may be disposed on the second layer L2.

A signal opposite to the signal of the touch line TL may be applied to the compensation line CL, and the signal TS (see FIG. 11) of the touch line TL may be compensated by the signal OMS (see FIG. 11) of the compensation line CL. However, it is not necessary that a magnitude of the opposite signal be equal to the opposite of a magnitude of the signal TS of the touch line TL. A magnitude of the signal OMS (see FIG. 11) of the compensation line CL may be adjusted according to influence which the signal MS (see FIG. 11) of the communication line ML and the signal OMS (see FIG. 11) of the compensation line CL have on the signal TS (see FIG. 11) of the touch line TL.

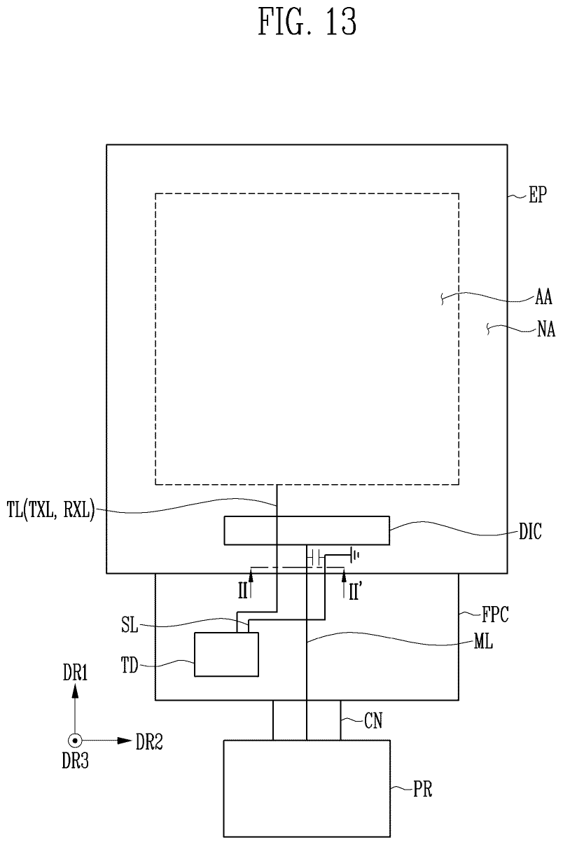

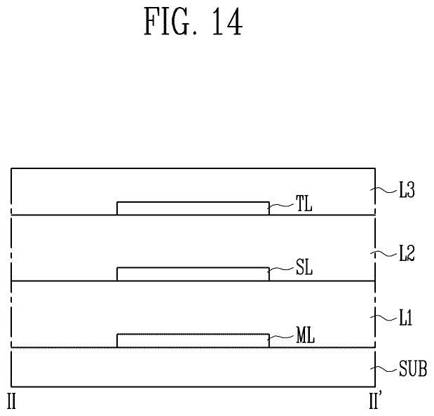

FIG. 13 is a plan view illustrating a display device in accordance with embodiments of the present disclosure. FIG. 14 is a sectional view taken along line II-II′ shown in FIG. 13.

In FIG. 13, for convenience of description, pads between an electronic panel EP, a flexible printed circuit FPC, a connection portion CN, and a processor PR will be omitted.

In FIG. 13, for convenience of description, although a specific line is disposed in a plurality of components (e.g., the electronic panel EP, the flexible printed circuit FPC, the connection portion CN, and the processor PR) through pads, the specific line will be regarded as one line.

For convenience of description, FIG. 13 illustrates that a touch line TL traverses a driver integrated circuit DIC. However, the present disclosure is not limited thereto. For example, the touch line TL may be connected to a touch driver TD bypassing the driver integrated circuit DIC.

For convenience of description, FIG. 13 illustrates that a sensing line SL, the touch line TL, and a communication line ML are spaced apart from each other. However, at least two of the sensing line SL, the touch line TL, and the communication line ML may partially overlap with each other on a plane.

FIG. 14 is for the purpose of illustrating relative positions between the lines ML, SL, and TL. For convenience of description, only a substrate SUB, a first layer L1, a second layer L2, and a third layer L3 are illustrated, and components between the first layer L1, the second layer L2, and the third layer L3 and on the third layer L3 will be omitted.

The display device in accordance with these embodiments is configured substantially identical to the display device shown in FIG. 8, except the display device in accordance with these embodiments includes the sensing line SL instead of the compensation line CL (see FIG. 8). Therefore, components identical or similar to those shown in FIG. 8 are designated by like reference numerals, and overlapping descriptions will be omitted.

Referring to FIGS. 13 and 14, the display device may further include the sensing line SL for sensing a signal of the communication line ML. The touch driver TD may sense a signal of the communication line ML through the sensing line SL. For example, the sensing line SL may be connected to the touch driver TD. The sensing line SL may form a capacitor with the communication line ML.

The sensing line SL may be adjacent to at least a portion of the communication line ML. For example, the sensing line SL may be adjacent to at least a portion of the communication line ML in a peripheral area NA. For example, the sensing line SL may extend to the electronic panel EP in the flexible printed circuit FPC.

In an embodiment, the sensing line SL may overlap with at least a portion of the communication line ML on a plane. For example, the sensing line SL may overlap with at least a portion of the communication line ML in the peripheral area NA.

At least a portion of the sensing line SL may be disposed between the touch line TL and the communication line ML on a section. For example, the second layer L2 including the sensing line SL may be disposed on the first layer L1 including the communication line ML, and the third layer L3 may be disposed on the second layer L2.

As the sensing line SL is adjacent to or overlaps with the communication line ML, a capacitor may be formed between the sensing line SL and the communication line ML. Accordingly, the touch driver TD may sense a signal of the communication line ML.

The touch driver TD may compensate for a signal of the touch line TL, based on the signal of the communication line ML. As described with reference to FIG. 10, noise may be generated in the touch line due to the communication line ML. The touch driver TD may predict noise by sensing the signal of the communication line ML, and compensate for the noise.

Similarly to what is shown in FIG. 11, as a signal of the sensing line SL is opposite to the signal MS of the communication line ML, noise caused by the communication line ML may be compensated.

In FIG. 14, it is illustrated that the sensing line SL and the touch line TL completely overlap with each other. However, the present disclosure is not limited thereto. For example, as the sensing line SL and the touch line TL are adjacent to each other, the signal TS of the touch line TL may be compensated even though the sensing line SL and the touch line TL partially overlap with each other or do not overlap with each other.

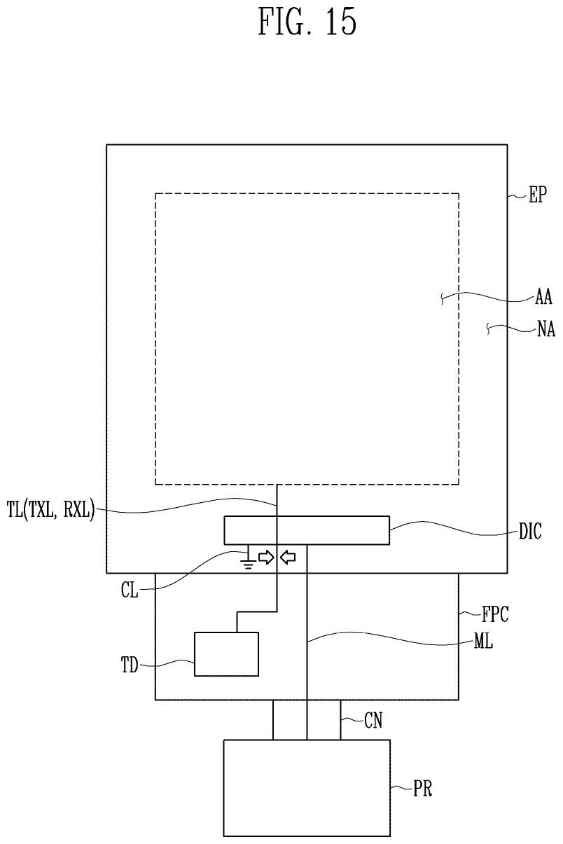

FIG. 15 is a plan view illustrating a display device in accordance with embodiments of the present disclosure.

In FIG. 15, for convenience of description, pads between an electronic panel EP, a flexible printed circuit FPC, a connection portion CN, and a processor PR will be omitted.

In FIG. 15, for convenience of description, although a specific line is disposed in a plurality of components (e.g., the electronic panel EP, the flexible printed circuit FPC, the connection portion CN, and the processor PR) through pads, the specific line will be regarded as one line.

For convenience of description, FIG. 15 illustrates that a touch line TL traverses a driver integrated circuit DIC. However, the present disclosure is not limited thereto. For example, the touch line TL may be connected to a touch driver TD bypassing the driver integrated circuit DIC.

For convenience of description, FIG. 15 illustrates that a compensation line CL, the touch line TL, and a communication line ML are spaced apart from each other. However, at least two of the compensation line SL, the touch line TL, and the communication line ML may partially overlap with each other on a plane.

The display device in accordance with these embodiments is configured substantially identical to the display device shown in FIG. 8, except that the driver integrated circuit DIC applies a signal to the compensation line CL. Therefore, components identical or similar to those shown in FIG. 8 are designated by like reference numerals, and overlapping descriptions will be omitted.

Referring to FIG. 15, the driver integrated circuit DIC may apply a signal opposite to the signal MS of the communication line ML to the compensation line CL. For example, the signal OMS of the compensation line CL may fall when the signal MS of the communication line ML rises, and rise when the signal MS of the communication line ML falls.

It is not necessary that a magnitude of the opposite signal be equal to the opposite of a magnitude of the signal MS of the communication line ML.

The compensation line CL may be adjacent to at least a portion of the touch line TL. For example, the compensation line CL may be adjacent to at least a portion of the touch line TL in a peripheral area NA.

In an embodiment, the compensation line CL may overlap with at least a portion of the touch line TL on a plane. For example, the compensation line CL may overlap with at least a portion of the touch line TL in the peripheral area NA.

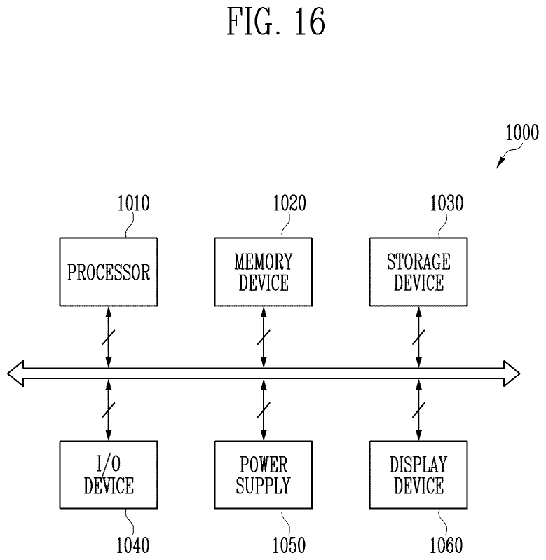

FIG. 16 is a block diagram illustrating an electronic device in accordance with embodiments of the present disclosure.

Referring to FIG. 16, the electronic device 1000 may include a processor 1010, a memory device 1020, a storage device 1030, an input/output (I/O) device 1040, a power supply, 1050, and a display device 1060. The display device 1060 may be the display device shown in FIG. 1. Also, the electronic device 1000 may further include several ports capable of communicating with a video card, a sound card, a memory card, a USB device, and the like, or communicating with other systems. In an embodiment, the electronic device 1000 may be implemented as a smartphone. However, this is merely illustrative, and the electronic device 1000 is not limited thereto. For example, the electronic device 1000 may be implemented as a mobile phone, a video phone, a smart pad, a smart watch, a tablet PC, a vehicle navigation system, a computer monitor, a notebook computer, a head mounted display device, or the like.

The processor 1010 may perform specific calculations or tasks. In some embodiments, the processor 1010 may be a microprocessor, a central processing unit, an application processor, or the like. The processor 1010 may be connected to other components through an address bus, a control bus, a data bus, and the like. In some embodiments, the processor 1010 may be connected to an extension bus such as a peripheral component interconnect (PCI) bus.

The memory device 1020 may store data necessary for an operation of the electronic device 1000. For example, the memory device 1010 may include a nonvolatile memory device such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM) device, or a Ferroelectric Random Access Memory (FRAM) device, or a volatile memory device such as a Dynamic Random Access Memory (DRAM) device, a Static Random Access Memory (SRAM) device, or a mobile DRAM device.

The storage device 1030 may include a Solid State Drive (SSD), a Hard Disk Drive (HDD), a CD-ROM, and the like.

The I/O device 1040 may include an input means such as a keyboard, a keypad, a touch screen, or a mouse, and an output means such as a speaker or a printer. In some embodiments, the display device 1060 may be included in the I/O device 1040.

The power supply 1050 may supply power necessary for an operation of the electronic device 1000. For example, the power supply 1050 may be a power management integrated circuit (PMIC).

The display device 1060 may display an image corresponding to visual information of the electronic device 1000. The display device 1060 may be an organic light emitting display device or a quantum dot light emitting display device, but the present disclosure is not limited thereto. The display device 1060 may be connected to other components through the buses or another communication link.

The present disclosure can be applied to display devices and electronic devices including the same. For example, the present disclosure can be applied to digital TVs, 3D TVs, mobile phones, smart phones, tablet computers, VR devices, PCs, home appliances, notebook computers, PDAs, PMPs, digital cameras, music players, portable game consoles, navigation systems, and the like.

In accordance with the present disclosure, the display device disposes a compensation line to which a signal opposite to a signal of a communication line is applied, to compensate for influence which the communication line has on a touch line.

In accordance with the present disclosure, the display device includes a sensing line for sensing a signal of a communication line, to sense a signal of the communication line and compensate for influence which the communication line has on a touch line, based on the sensed signal.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, or elements described in connection with a particular embodiment may be used singly or in combination with features, characteristics, or elements described in connection with other embodiments unless otherwise specifically indicated. Accordingly, it will be understood by those of skill in the art that various changes in form and details may be made without departing from the spirit and scope of the present disclosure as set forth in the following claims.

1. A display device comprising:
an electronic panel including a touch panel and a display panel, the touch panel includes a touch electrode and the display panel includes a pixel;
a driver integrated circuit that provides a data voltage to the pixel, the driver integrated circuit communicates with a processor through a communication line;
a touch driver connected to the touch electrode through a touch line, the touch driver drives the touch panel; and
a compensation line to which a signal opposite to a signal of the communication line is applied.

2. The display device of claim 1, wherein the compensation line overlaps with at least a portion of the touch line on a plane.

3. The display device of claim 1, wherein the communication line overlaps with at least a portion of the touch line on a plane.

4. The display device of claim 1, wherein the compensation line is adjacent to at least a portion of the touch line.

5. The display device of claim 1, wherein at least a portion of the compensation line is disposed on the touch line.

6. The display device of claim 1, wherein at least a portion of the compensation line is disposed between the touch line and the communication line.

7. The display device of claim 1, wherein the touch driver applies the signal opposite to the signal of the communication line to the compensation line.

8. The display device of claim 7, wherein the touch driver is disposed on a flexible printed circuit connected to the electronic panel, and
wherein the compensation line extends to the electronic panel in the flexible printed circuit.

9. The display device of claim 8, wherein the compensation line is adjacent to the touch line in the electronic panel.

10. The display device of claim 1, wherein the driver integrated circuit applies the signal opposite to the signal of the communication line to the compensation line.

11. The display device of claim 10, wherein the driver integrated circuit is disposed in the electronic panel, and
wherein the compensation line is adjacent to the touch line in the electronic panel.

12. A display device comprising:
an electronic panel including a touch panel and a display panel, the touch panel includes a touch electrode and the display panel includes a pixel;
a driver integrated circuit that provides a data voltage to the pixel, the driver integrated circuit communicates with a processor through a communication line; and
a touch driver connected to the touch electrode through a touch line, the touch driver drives the touch panel, the touch driver senses a signal of the communication line through a sensing line, the touch driver compensates for a signal of the touch line based on the signal of the communication line.

13. The display device of claim 12, wherein the sensing line overlaps with at least a portion of the communication line on a plane.

14. The display device of claim 12, wherein the sensing line forms a capacitor with the communication line on a plane.

15. The display device of claim 12, wherein the communication line overlaps with at least a portion of the touch line on a plane.

16. The display device of claim 12, wherein the sensing line is adjacent to at least a portion of the communication line.

17. The display device of claim 12, wherein at least a portion of the sensing line is disposed between the communication line and the touch line.

18. The display device of claim 12, wherein the touch driver is disposed in a flexible printed circuit connected to the electronic panel, and
wherein the sensing line extends to the electronic panel in the flexible printed circuit.

19. The display device of claim 18, wherein the sensing line is adjacent to the communication line in the electronic panel.

20. An electronic device, comprising:
a processor to provide input image data; and
a display device to display an image based on the input image data,
the display device comprising:
an electronic panel including a touch panel and a display panel, the touch panel includes a touch electrode and the display panel includes a pixel;
a driver integrated circuit that provides a data voltage to the pixel, the driver integrated circuit communicates with a processor through a communication line;
a touch driver connected to the touch electrode through a touch line, the touch driver drives the touch panel; and
a compensation line to which a signal opposite to a signal of the communication line is applied.

21. The electronic device of claim 20, wherein the compensation line overlaps with at least a portion of the touch line on a plane.

22. The electronic device of claim 20, wherein the communication line overlaps with at least a portion of the touch line on a plane.

23. The electronic device of claim 20, wherein the compensation line is adjacent to at least a portion of the touch line.
